(19) United States
(12) Patent Application Publication
(10) Pub. No.: US 2001/0017769 A1
(43) Pub. Date: Aug. 30, 2001

(54) Printed circuit board and method for mounting electrical component thereon

(76) Inventor: Kiyoshi Ito, Tokyo (JP)

Correspondence Address: PILLSBURY WINTHROP LLP, 1600 TYSONS BOULEVARD, MCLEAN, VA, 22102, US

(21) Appl. No.: 09/748,148

(22) Filed: Dec. 27, 2000

(30) Foreign Application Priority Data
Dec. 27, 1999 (JP) 11-371051
Dec. 28, 1999 (JP) 11-373934

(51) Int. Cl. H05K 1/18

(52) U.S. Cl. 361/761

(57) ABSTRACT

A printed circuit board and a method for mounting an electrical component thereon, which can decrease spacing between electrical elements mounted on the printed circuit board, by mounting a predetermined electrical element in an inside of the printed circuit board, and which can reduce an electric characteristic inductance by decreasing a length of a conductive pattern of the printed circuit board. The printed circuit board (2) made of insulating member, comprises: a surface conductive pattern formed on a surface of the printed circuit board; a concave portion for opening to a surface (2a) of the printed circuit board, wherein a predetermined electrical component (3) can be embedded; and an internal conductive pattern (4a and 4b) for connecting a predetermined electrical component embedded in the concave portion to another electrical component mounted on the surface conductive pattern.

### BACKGROUND OF THE INVENTION

1. Field of the Invention

The present invention relates to a printed circuit board used in a semiconductor testing device for a characteristic test of IC and a method for mounting an electrical component on the printed circuit board.

2. Description of Related Art

Such electrical components as IC socket, a condenser and so on are mounted on a printed circuit board (for example, DUT board or the like) used in a semiconductor testing device.

A printed circuit board and a method for mounting an electrical component thereon according to an earlier development will be explained with reference to FIGS. 5 and 6, as follows.

FIG. 5 is a view showing a state in which electrical components are mounded on a printed circuit board 200 according to an earlier development. In FIG. 5, the reference numeral 1 denotes IC socket, the reference numeral 200 denotes a printed circuit board, the reference numeral 3 denotes a by-pass condenser, the reference numerals 400a and 400b denote conductive patterns and the reference numeral 500 denotes a solder.

A plurality of through holes 200c pass through the printed circuit board 200 in the perpendicular direction to a front surface 200a and a rear surface 200b of the printed circuit board 200. Each of a plurality of leads 11 of IC socket 1 is inserted in each through hole 200c from the side of the front surface 200a to the side of the rear surface 200b, and soldered to the rear surface 200b (not shown).

The conductive patterns 400a and 400b are formed on the rear surface 200b of the printed circuit board 200. The conductive patterns 400a and 400b are electrically connected to the lead 11 of the IC socket 1 by soldering the lead 11 to the rear surface 200b.

The by-pass condenser 3 is mounted on the rear surface 200b of the printed circuit board 200. Metal portions 3a are formed on both side surfaces of the by-pass condenser 3, respectively. And further, each metal portion 3 is electrically connected to the conductive pattern 400b formed on the rear surface 200b of the printed circuit board 200, through the solder 500.

FIG. 6 is a view showing a state in which electrical components are mounted on a multilayer printed circuit board composed of printed circuit boards 201, 202 and 203 according to an earlier development. In FIG. 6, the same reference numerals are attached to the same elements, structures and the like as those of FIG. 5.

A plurality of through holes 201c, 202c and 203c pass through printed circuit boards 201, 202 and 203, respectively. Each of a plurality of leads 11 of IC socket 1 is inserted in each through hole 201c, 202c and 203c, and soldered to a rear surface 203b of the printed circuit board 203 (not shown).

Conductive patterns 401, 402a to 402c, and 403a to 403b are formed on the printed circuit boards 201, 202 and 203, and electrically connected to the lead 11 of the IC socket 1 by inserting the lead 11 in the through holes 201c, 202c and 203c, respectively.

A conductive pattern 403c is electrically connected to the conductive pattern 403b through a through hole 203d.

The by-pass condenser 3 is mounted on a rear surface 202b of the printed circuit board 202. Metal portions 3 formed on both side surfaces of the by-pass condenser 4, are electrically connected to the conductive patterns 402b formed on the rear surface 202b of the printed circuit board 202, through solders 502.

However, as described above, when the by-pass condenser 3 is mounted on the printed circuit board 200 or the printed circuit board 202, the area on which the by-pass condenser 3 is mounted becomes large because the necessary area for solder (501 or 502) is large. Accordingly, even if the outside dimension of the by-pass condenser 3 is reduced, there has been a problem impossible of miniaturizing the printed circuit boards 200 and 202.

Further, the electric characteristic impedance becomes large because the conductive patters 400b and 402b are longer by the lengths of the solders 500 and 502, respectively. Accordingly, there has been a problem of lowing the effect of reducing noise.

### SUMMARY OF THE INVENTION

The present invention was developed in view of the above-described problems.

An object of the present invention is to provide a printed circuit board and a method for mounting an electrical component thereon, which can decrease spacing between electrical elements mounted on the printed circuit board, by mounting a predetermined electrical element in an inside of the printed circuit board.

Another object of the present invention is to provide a printed circuit board and a method for mounting an electrical component thereon, which can reduce an electric characteristic inductance by decreasing a length of a conductive pattern of the printed circuit board.

In accordance with one aspect of the present invention, a printed circuit board (for example, a printed circuit board 2 or 20 shown in FIG. 1 or FIG. 2) made of insulating member, comprises: a surface conductive pattern formed on a surface of the printed circuit board; a concave portion for opening to a surface (for example, a front surface 2a or 20a shown in FIG. 1 or FIG. 2) of the printed circuit board, wherein a predetermined electrical component (for example, a condenser 3 shown in FIG. 1 or FIG. 2) can be embedded; and an internal conductive pattern (for example, conductive patterns 4a and 4b or 40a and 40b shown in FIG. 1 or FIG. 2) for connecting a predetermined electrical component embedded in the concave portion to another electrical component mounted on the surface conductive pattern.

The surface conductive pattern is omitted to be shown in figures, but is formed on a least one surface of the printed circuit board. The concave portion is omitted to be shown in figures, but is formed, for example, by shaping one portion of the printed circuit board.

Preferably, according to the printed circuit board made of insulating member, as described above, the concave portion is formed at a position on the printed circuit board so that a length of the internal conductive pattern is shortest.

In accordance with another aspect of the present invention, a method for mounting an electrical component on a printed circuit board made of insulating member and having a surface conductive pattern on a surface thereof, comprises the steps of: forming a concave portion for opening to a surface of the printed circuit board, wherein a predetermined electrical component can be embedded; forming an internal conductive pattern for connecting a predetermined electrical component embedded in the concave portion to another electrical component mounted on the surface conductive pattern; and mounting a predetermined electrical component in the concave portion so as to be connected to the internal conductive pattern.

Preferably, according to the method for mounting an electrical component on a printed circuit board made of insulating member and having a surface conductive pattern on a surface thereof, as described above, the concave portion is formed at a position on the printed circuit board so that a length of the internal conductive pattern is shortest.

According to the printed circuit board or the method for mounting an electrical component thereon, as described above, a predetermined electrical component is embedded in the concave portion formed on the printed circuit board, thereby it is possible to decrease a length of the internal conductive pattern connecting the predetermined electrical component to another electrical component mounted on the surface conductive pattern.

Consequently, it is possible to decrease spacing between electrical components so that it is possible to miniaturize the printed circuit board. Further, it is possible to decrease the length of the internal conductive pattern so that it is possible to reduce an electrical characteristic inductance of the printed circuit board.

Preferably, the printed circuit board made of insulating member, as described above, further comprises: a conductive sheet (for example, a conductive sheet 6 shown in FIG. 2) through which the internal conductive pattern can be connected to the predetermined electrical component embedded in the concave portion.

Preferably, the method for mounting an electrical component on a printed circuit board made of insulating member and having a surface conductive pattern on a surface thereof, as described above, further comprises the step of: placing a conductive sheet through which the internal conductive pattern can be connected to the predetermined electrical component mounted in the concave portion, on the internal conductive pattern.

According to the printed circuit board or the method for mounting an electrical component thereon, as described above, the predetermined electrical component is connected to the internal conductive pattern through the conductive sheet, thereby, for example, it is possible to decrease the length of the internal conductive pattern more than the predetermined electrical component is soldered to the internal conductive pattern. Consequently, it is possible to decrease spacing of mounting an electrical component on the printed circuit board.

In accordance with a further aspect of the present invention, a printed circuit board made of insulating member, comprises: a surface conductive pattern formed on a surface of the printed circuit board; a through hole (for example, a through hole shown in FIG. 3) for passing through the printed circuit board (for example, a printed circuit board 22 shown in FIG. 3), wherein a predetermined electrical component can be mounted; and an internal conductive pattern for connecting a predetermined electrical component mounted in the through hole to another electrical component mounted on the surface conductive pattern.

Preferably, according to the printed circuit board made of insulating member, as described above, the through hole is formed at a position on the printed circuit board so that a length of the internal conductive pattern is shortest.

In accordance with a further aspect of the present invention, a method for mounting an electrical component on a printed circuit board made of insulating member and having a surface conductive pattern on a surface thereof, comprises the steps of: forming a through hole for passing through the printed circuit board, wherein a predetermined electrical component can be mounted; forming an internal conductive pattern for connecting a predetermined electrical component mounted in the through hole to another electrical component mounted on the surface conductive pattern; and mounting a predetermined electrical component in the through hole so as to be connected to the internal conductive pattern.

Preferably, according to the method for mounting an electrical component on a printed circuit board made of insulating member and having a surface conductive pattern on a surface thereof, as described above, the concave portion is formed at a position on the printed circuit board so that a length of the internal conductive pattern is shortest.

According to the printed circuit board or the method for mounting an electrical component thereon, as described above, a predetermined electrical component is mounted in the through hole formed on the printed circuit board, thereby it is possible to decrease a length of the internal conductive pattern connecting the predetermined electrical component to another electrical component mounted on the surface conductive pattern. Consequently, it is possible to decrease spacing between electrical components so that it is possible to miniaturize the printed circuit board. Further, it is possible to decrease the length of the internal conductive pattern so that it is possible to reduce an electrical characteristic inductance of the printed circuit board.

Further, the predetermined electrical component is mounted in the through hole, thereby it is possible to reduce a thickness of the printed circuit board in which the predetermined electrical component is mounted. Consequently, it is possible to decrease a distance between printed circuit boards of a multilayer printed circuit board so that it is possible to miniaturize the multilayer printed circuit board.

### BRIEF DESCRIPTION OF THE DRAWINGS

The present invention will become more fully understood from the detailed description given hereinafter and the accompanying drawings which are given by way of illustration only, and thus are not intended as a definition of the limits of the present invention, and wherein:

FIG. 1 is a view showing a state in which electrical elements are mounted on a printed circuit board 2, according to an embodiment of the present invention;

FIG. 2 is a view showing a state in which electrical elements are mounted on a printed circuit board 20, according to another embodiment of the present invention;

FIG. 3 is a view showing a state in which electrical elements are mounted on a multilayer printed circuit board composed of printed circuit boards 21, 22 and 23, according to a further embodiment of the present invention;

FIG. 4 is a view showing a state in which electrical elements are mounted on a multilayer printed circuit board composed of printed circuit boards 21, 24 and 23, according to a further embodiment of the present invention;

FIG. 5 is a view showing a state in which electrical elements are mounted on a printed circuit board 200, according to an earlier development; and

FIG. 6 is a view showing a state in which electrical elements are mounted on a multilayer printed circuit board composed of printed circuit boards 201, 202 and 203, according to an earlier development.

### PREFERRED EMBODIMENT OF THE INVENTION

Hereinafter, an embodiment of the printed circuit board of the present invention will be explained with reference to FIGS. 1 to 4, in detail.

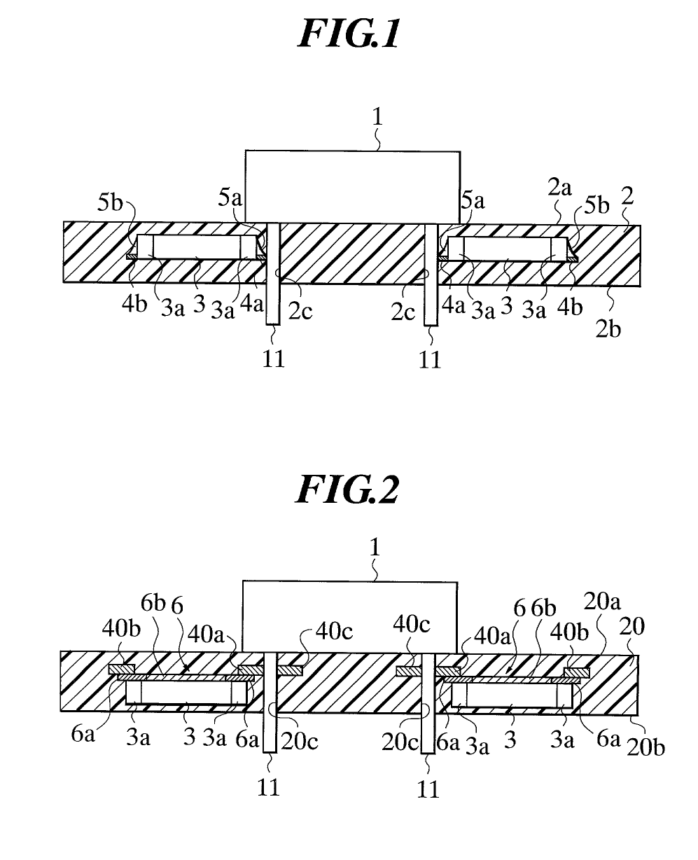

FIG. 1 is a view showing a state in which electrical elements are mounted on the printed circuit board 2, according to an embodiment of the present invention. FIG. 2 is a view showing a state in which electrical elements are mounted on the printed circuit board 20, according to another embodiment of the present invention.

In FIG. 1, the reference numeral 1 denotes IC socket, the reference numeral 2 denotes a printed circuit board, the reference numeral 3 denotes a by-pass condenser, and the reference numerals 4a and 4a denote conductive patters.

IC socket 1 is a lead-through member in which IC as an object of test is mounted. IC socket 1 comprises a plurality of leads 11 inserted in a plurality of through holes 2c passing through the printed circuit board 2 in the perpendicular direction thereof and soldered to the rear surface 2b of the printed circuit board 2.

The printed circuit board 2 comprises the by-pass condenser 3 and the conductive patters 4a and 4b mounted in an inside thereof. The conductive patterns 4a and 4b are electrically connected to metal portions 3a formed on both side surfaces of the by-pass condenser 3, through the solders 5a and 5b, respectively.

Further, the printed circuit board 2 further comprises a plurality of through holes 2c passing in the perpendicular direction to the front surface 2a and the rear surface 2b thereof.

The by-pass condenser 3 is a condenser for reducing noise occurred on the printed circuit board 2, and mounted in the inside of the printed circuit board 2. The by-pass condenser 3 comprises metal portions 3a formed on both side surfaces thereof and electrically connected to the conductive patterns 4a and 4b through the solders 5a and 5b, respectively.

In FIG. 2, the printed circuit board 20 comprises the by-pass condenser 3 mounted in an inside thereof. Herein, the same reference numerals are attached to the same elements, structures and the like as those of FIG. 1, and the explanation of the same elements will be omitted.

The pointed of difference between the printed circuit board 20 shown in FIG. 2 and the printed circuit board 2 shown in FIG. 1 will be explained, as follows.

According to the by-pass condenser 3 and the conductive patterns 40a and 40b mounted in the inside of the printed circuit board 20, the metal portions 3a formed on both side surfaces of the by-pass condenser 3 are electrically connected to the conductive patterns 40a and 40b through the conductive sheet 6, not the solders.

The conductive sheet 6 is composed of conductive portions 6a formed at both edges thereof and an insulating portion 6b formed in a center thereof. The conductive sheet 6 is, for example, an anisotropic conductive sheet. When the conductive sheet 6 is compressed in the predetermined direction, the conductive sheet 6 has conductivity in the compression direction to form the conductive portions 6a and the insulating portion 6b.

That is, according to the conductive sheet 6, the portions compressed by the conductive patterns 40a and 40b and the by-pass condenser 3 are the conductive portions 6a, while the portion not compressed is the insulating portion 6b.

Accordingly, the metal portions 3a formed on both side surfaces of the by-pass condenser 3 are conducted to the conductive patterns 40a and 40b through the conductive portions 6a.

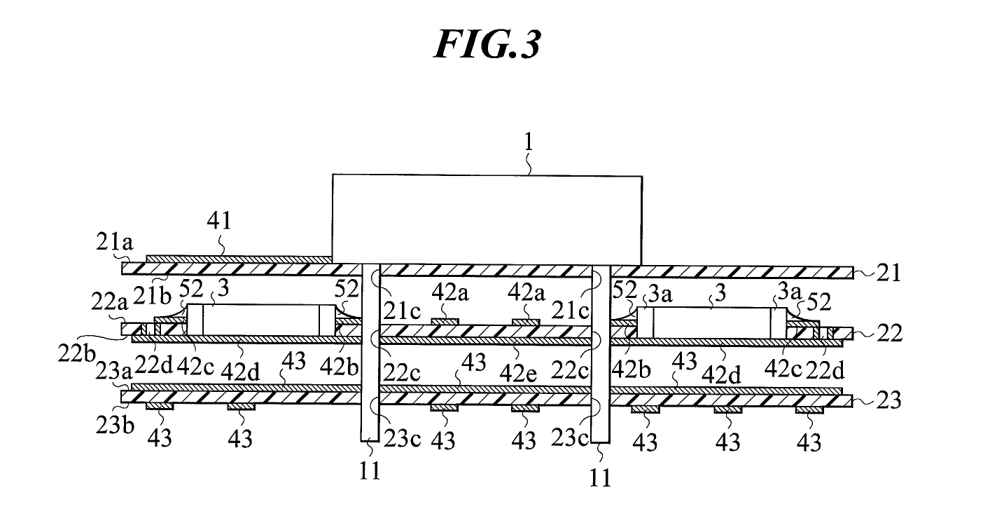

FIG. 3 is a view showing a state in which electrical elements are mounted on the multilayer printed circuit board composed of printed circuit boards 21, 22 and 23, according to a further embodiment of the present invention.

As shown in FIG. 3, a plurality of printed circuit boards 21, 22 and 23 are laminated.

IC socket 1 comprises a plurality of leads 11 inserted in a plurality of through holes 21c, 22c and 23c passing through the printed circuit boards 21, 22 and 23 in the perpendicular direction thereof and soldered to the rear surface 23b of the printed circuit board 23 (not shown).

The conductive patterns 41, 42a to 42e, and 43 formed on the printed circuit boards 21, 22 and 23 are electrically connected to one another through the leads 11 inserted in the through holes 21c, 22c and 23c, respectively. Further, the conductive pattern 42c is electrically connected to the conductive patter 42d through the through hole 22d.

The printed circuit board 22 comprises a through hole which passes through the printed circuit board 22 in the vertical direction and to which the by-pass condenser 3 is fitted.

The by-pass condenser 3 is a condenser for reducing noise occurred on the printed circuit board. The by-pass condenser 3 comprises metal portions 3a formed on both side surfaces thereof and electrically connected to the conductive patterns 42b and 42c through the solders 52.

Next, a method for mounting electrical components on the printed circuit board will be briefly explained with reference to FIGS. 1 to 3, as follows.

First, the method for mounting electrical components on the printed circuit board 2 will be explained with reference to FIG. 1.

As shown in FIG. 1, the printed circuit board 2 is prepared, wherein a plurality of through holes 2c are formed so as to pass through the printed circuit board 2 in the vertical direction, a concave portion (not shown) in which the by-pass condenser 3 can be embedded is formed on the front surface 2a of the printed circuit board 2 and the conductive patterns 4a and 4b are formed at both sides of the concave portion of the printed circuit board 2.

The by-pass condenser 3 is embedded in the concave portion of the printed circuit board 2. Metal portions 3a formed at both sides of the by-pass condenser 3 are connected to the conductive patterns 4a and 4b by the solders 5a and 5b, respectively.

The concave portion in which the by-pass condenser 3 is embedded is filled with the resin.

The leads 11 of IC socket 1 is inserted in the through holes 2c and soldered on the rear surface 2b of the printed circuit board 2.

As described above, the by-pass condenser 3 is mounted in the inside of the printed circuit board 2 and IC socket 1 is mounted on the front surface 2a of the printed circuit board 2.

Next, the method for mounting electrical components on the printed circuit board 20 will be explained with reference to FIG. 2.

As shown in FIG. 2, like the method for mounting electrical components on the printed circuit boards 2, the printed circuit board 20 is prepared, wherein a plurality of through holes 20c are formed so as to pass through the printed circuit board 20 in the vertical direction and a concave portion (not shown) in which the by-pass condenser 3 can be embedded is formed on the front surface 20a of the printed circuit board 20.

The by-pass condenser 30 is embedded in the concave portion of the printed circuit board 20. The conductive sheet 6 is placed on the by-pass condenser 3, and the conductive patterns 40a and 40b are placed on the conductive sheet 6. The pressure is applied to the conductive sheet 6 through the conductive patterns 40a and 40b.

The concave portion in which the by-pass condenser 3 is embedded is filled with the resin.

The leads 11 of IC socket 1 is inserted in the through holes 2c and soldered on the rear surface 20b of the printed circuit board 20.

As described above, the by-pass condenser 3 is mounted in the inside of the printed circuit board 20 and IC socket 1 is mounted on the front surface 20a of the printed circuit board 20.

Next, the method for mounting electrical components on the multilayer printed circuit board composed of the printed circuit boards 21, 22 and 23 will be explained with reference to FIG. 3.

As shown in FIG. 3, the printed circuit boards 21, 22 and 23 are prepared, wherein a plurality of through holes 21c, 22c and 22d, and 23c are formed so as to pass through the printed circuit boards 21, 22 and 23 in the vertical direction, the conductive patterns 41, 42a to 42e, and 43 are formed on the printed circuit boards 21, 22 and 23, respectively, and a through hole in which the by-pass condenser 3 can be mounted is formed on the printed circuit board 22.

The by-pass condenser 3 is fitted in the through hole of the printed circuit board 2. Metal portions 3a formed at both sides of the by-pass condenser 3 are connected to the conductive patterns 42b and 42c formed on the front surface 22a of the printed circuit board 22 by the solders 52.

The printed circuit board 21, 22 and 23 are laminated. The leads 11 of IC socket 1 is inserted in the through holes 21c, 22c and 23c of the printed circuit boards 21, 22 and 23, from the side of the front surface 21a to the side of the rear surface 23b and soldered on the rear surface 23b of the printed circuit board 23.

As described above, the by-pass condenser 3 is mounted on the printed circuit board 22 and IC socket 1 is mounted on the front surface 21a of the printed circuit board 21.

As described above, according to the embodiment shown in FIG. 1, of the present invention, the concave portion in which the by-pass condenser 3 can be embedded, is formed on the front surface 2a of the printed circuit board 2, and the by-pass condenser 3 is embedded in the concave portion. Further, metal portions 3a formed on both side surfaces of the by-pass condenser 3 are connected to the conductive patterns 4a and 4b formed at the concave portion of the printed circuit board 2, by the solders 5a and 5b, respectively. Thereafter, the concave portion is filled with the resin. Therefore, the by-pass condenser is mounted in the inside of the printed circuit board 2.

Thereafter, the lead 11 of IC socket 1 is inserted in the through hole 2c of the printed circuit board 2, and soldered on the rear surface 2b of the printed circuit board 2. Therefore, IC socket 1 is mounted on the front surface 2a of the printed circuit board 2.

Accordingly, the by-pass condenser 3 is mounted in the inside of the printed circuit board 2, thereby it is possible to reduce the necessary area for the solder (5a) and it is possible to decrease the distance between the by-pass condenser 3 and IC socket 1. Consequently, it is possible to miniaturize the printed circuit board 2.

Further, it is possible to decrease the length of the conductive pattern 4a connecting the by-pass condenser 3 to IC socket 1. Consequently, it is possible to reduce an electric characteristic inductance of the printed circuit board.

According to the embodiment shown in FIG. 2, of the present invention, the by-pass condenser 3 mounted in the inside of the printed circuit board 20 is connected to the conductive patterns 40a and 40b through the conductive sheet 6. Therefore, it is possible to decrease the lengths of the conductive patterns 40a and 40b more than the by-pass condenser 3 is connected to the conductive patterns 40a and 40b by solders, thereby it is possible to decrease the distance between IC socket 1 and by-pass condenser 3.

Accordingly, it is possible to miniaturize the printed circuit board 20 and it is possible to reduce an electric characteristic inductance of the printed circuit board 20.

Further, the conductive sheet 6 is used in the printed circuit board 20 so that the step of soldering in the inside of the printed circuit board 20 becomes unnecessary. Consequently, it becomes easy that an electrical component is mounted in the inside of the printed circuit board 20.

In the case that the thickness of the printed circuit board 2 is thin, according to the embodiment shown in FIG. 3, of the present invention, the through hole is formed on the printed circuit board 22, and the by-pass condenser 3 is mounted in the through hole. Metal portions 3a formed on both side surfaces of the by-pass condenser 3 are connected to the conductive patterns 42b and 42c formed on the front surface 22a of the printed circuit board 22, by the solders 52. Therefore, the by-pass condenser 3 is mounted on the printed circuit board 22.

Accordingly, the by-pass condenser 3 is mounted in the through hole on the printed circuit board 22, thereby it is possible to reduce the necessary area for the solder (52) and it is possible to decrease the distance between the by-pass condenser 3 and IC socket 1. Consequently, it is possible to miniaturize the printed circuit board 20.

Further, the by-pass condenser 3 is mounted in the through hole on the printed circuit board 22, thereby the thickness of the printed circuit board 22 in which electrical components are mounted becomes thin. Consequently, it is possible to miniaturize the multilayer printed circuit board composed of the printed circuit boards 21, 22 and 23.

Although the present invention has been explained according to the above-described embodiment, it should also be understood that the present invention is not limited to the embodiment and various changes and modifications may be made to the invention without departing from the gist thereof.

For example, according to the embodiment shown in FIG. 3, it is explained that the by-pass condenser 3 is mounted on the printed circuit board 22 by being fitted in the through hole, because the thickness of the printed circuit board 22 is thin.

However, if the printed circuit board 22 has the sufficient thickness to mount the by-pass condenser 3 in the inside thereof, like the printed circuit board 2 shown in FIG. 1, the concave portion in which the by-pass condenser 3 can embedded may be formed on the printed circuit board 22 and the by-pass condenser 3 may be mounted in the inside of the printed circuit board 22.

Further, according to the embodiments shown in FIGS. 1 and 2, after the by-pass condenser 3 is embedded in each concave portion of the printed circuit boards 2 and 20, the concave portion is filled with resin.

However, if the printed circuit boards 2 and 20 are not contacted with another printed circuit board, that is, the printed circuit boards 2 and 20 are insulated from another printed circuit board, it is unnecessary that the concave portion is filled with resin. For example, according to the multilayer printed circuit board, a pripreg (a sheet made of carbon fiber or the like containing a resin) is usually used as insulation of the printed circuit board.

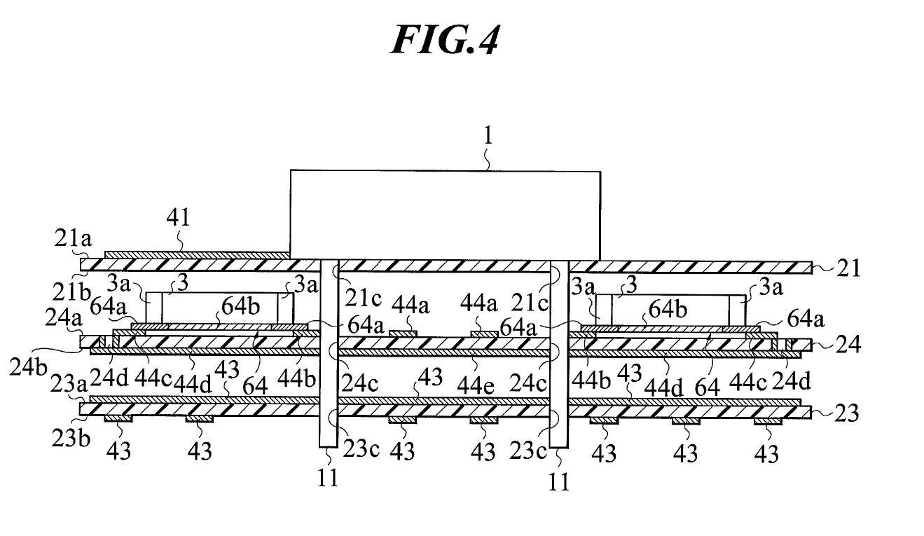

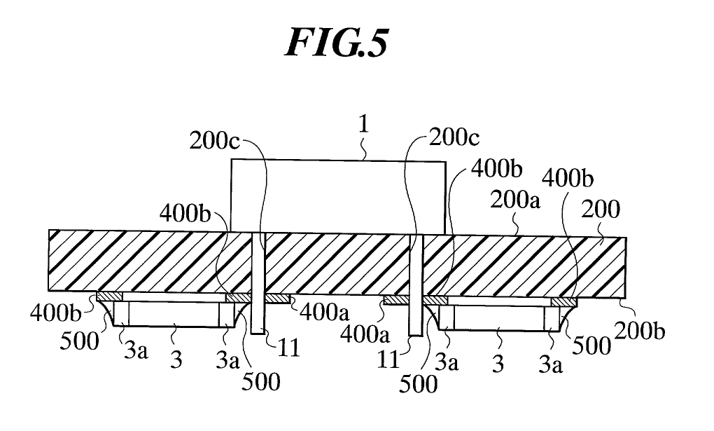

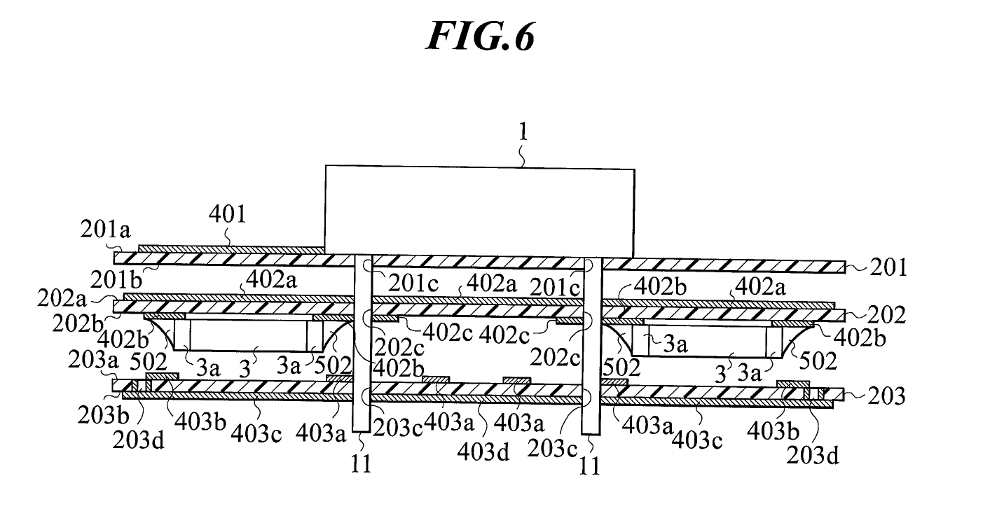

Hereinafter, a modified example according to the embodiment of the present invention will be explained with reference to FIG. 4, as follows.

FIG. 4 is a view showing a state in which electrical components are mounted on the multilayer printed circuit board composed of the printed circuit boards 21, 24 and 23.

According to the multilayer printed circuit board shown in FIG. 4, a plurality of the printed circuit boards 21, 22 and 23 are laminated. The same reference numerals are attached to the same elements, structures and the like as those of FIG. 3.

Herein, the printed circuit board 24 as the pointed of difference from the multilayer printed circuit board composed of the printed circuit boards 21, 22 and 23, shown in FIG. 3, will be explained mainly.

In FIG. 4, the conductive patterns 44b and 44c are formed on the front surface 24a of the printed circuit board 24. The conductive sheet 64 is placed on the conductive patterns 44b and 44c. The by-pass condenser 3 is mounted on the conductive sheet 64.

Metal portions 3a formed on both side surfaces of the by-pass condenser 3 mounted on the conductive sheet 64 are electrically connected to the conductive patterns 44b and 44c formed on the front surface 24a of the printed circuit board 24, through the conductive portions 64a formed at both edges of the conductive sheet 64.

Therefore, the by-pass condenser 3 is connected to the conductive patters 44b and 44c through the conductive sheet 64 so that it is possible to decrease the length of the conductive patters more than the by-pass condenser 3 is connected to the conductive patters by the solders.

The conductive sheet 64 is composed of conductive portions 64a formed at both edges thereof and an insulating portion 64b formed in a center thereof. The conductive sheet 64 is, for example, an anisotropic conductive sheet. When the conductive sheet 64 is compressed in the predetermined direction, the conductive sheet 64 has conductivity in the compression direction to form the conductive portions 64a and the insulating portion 64b.

That is, according to the conductive sheet 64, the portions compressed by the conductive patterns 44b and 44c and the by-pass condenser 3 are the conductive portions 64a, while the portion not compressed is the insulating portion 64b.

Accordingly, the metal portions 3a formed on both side surfaces of the by-pass condenser 3 are conducted to the conductive patterns 44b and 44c through the conductive portions 64a.

Next, the method for mounting electrical components on the multilayer printed circuit board composed of the printed circuit boards 21, 24 adn 23 will be explained with reference to FIG. 4.

As shown in FIG. 4, the printed circuit boards 21, 24 and 23 are prepared, wherein a plurality of through holes 21c, 24c and 24d, and 23c are formed so as to pass through the printed circuit boards 21, 24 and 23 in the vertical direction, and the conductive patterns 41, 44a to 44e, and 43 are formed on the printed circuit boards 21, 24 and 23, respectively.

The conductive patterns 44b and 44c are formed on the printed circuit board 24. The conductive sheet 64 is placed on the conductive patterns 44b and 44c. The by-pass condenser 3 is mounted on the conductive sheet 64. Thereafter, the pressure is applied to the conductive sheet 6 through the by-pass condenser 3.

The printed circuit board 21, 24 and 23 are laminated. The leads 11 of IC socket 1 is inserted in the through holes 21c, 24c and 23c of the printed circuit boards 21, 24 and 23, from the side of the front surface 21a to the side of the rear surface 23b and soldered on the rear surface 23b of the printed circuit board 23.

As described above, the by-pass condenser 3 is mounted on the printed circuit board 24 and IC socket 1 is mounted on the front surface 21a of the printed circuit board 21.

If the printed circuit board 24 has the sufficient thickness to mount the by-pass condenser 3 in the inside thereof, like the printed circuit board 20 shown in FIG. 2, the concave portion in which the by-pass condenser 3 can be embedded may be formed on the printed circuit board 24 and the by-pass condenser 3 may be mounted in the inside of the printed circuit board 24.

According to the present invention, a main effect can be obtained, as follows.

According to the printed circuit board or the method for mounting an electrical component thereon, as described above, a predetermined electrical component is embedded in the concave portion formed on the printed circuit board, thereby it is possible to decrease a length of the internal conductive pattern connecting the predetermined electrical component to another electrical component mounted on the surface conductive pattern.

Consequently, it is possible to decrease spacing between electrical components so that it is possible to miniaturize the printed circuit board. Further, it is possible to decrease the length of the internal conductive pattern so that it is possible to reduce an electrical characteristic inductance of the printed circuit board.

The entire disclosures of Japanese Patent Application Nos. Tokugan hei-11-371051 filed on Dec. 27, 1999 and Tokugan hei-11-373934 filed on Dec. 28, 1999, including specifications, claims, drawings and summaries, are incorporated herein by reference in its entirety.

What is claimed is:

1. A printed circuit board made of insulating member, comprising:
a surface conductive pattern formed on a surface of the printed circuit board;
a concave portion for opening to a surface of the printed circuit board, wherein a predetermined electrical component can be embedded; and
an internal conductive pattern for connecting a predetermined electrical component embedded in the concave portion to another electrical component mounted on the surface conductive pattern.

2. A printed circuit board made of insulating member, according to claim 1,
wherein the concave portion is formed at a position on the printed circuit board so that a length of the internal conductive pattern is shortest.

3. A printed circuit board made of insulating member, according to claim 1, further comprising:
a conductive sheet through which the internal conductive pattern can be connected to the predetermined electrical component embedded in the concave portion.

4. A printed circuit board made of insulating member, according to claim 2, further comprising:
a conductive sheet through which the internal conductive pattern can be connected to the predetermined electrical component embedded in the concave portion.

5. A printed circuit board made of insulating member, comprising:
a surface conductive pattern formed on a surface of the printed circuit board;
a through hole for passing through the printed circuit board, wherein a predetermined electrical component can be mounted; and
an internal conductive pattern for connecting a predetermined electrical component mounted in the through hole to another electrical component mounted on the surface conductive pattern.

6. A printed circuit board made of insulating member, according to claim 5,
wherein the through hole is formed at a position on the printed circuit board so that a length of the internal conductive pattern is shortest.

7. A method for mounting an electrical component on a printed circuit board made of insulating member and having a surface conductive pattern on a surface thereof, comprising the steps of:
forming a concave portion for opening to a surface of the printed circuit board, wherein a predetermined electrical component can be embedded;
forming an internal conductive pattern for connecting a predetermined electrical component embedded in the concave portion to another electrical component mounted on the surface conductive pattern; and
mounting a predetermined electrical component in the concave portion so as to be connected to the internal conductive pattern.

8. A method for mounting an electrical component on a printed circuit board made of insulating member and having a surface conductive pattern on a surface thereof, according to claim 7,
wherein the concave portion is formed at a position on the printed circuit board so that a length of the internal conductive pattern is shortest.

9. A method for mounting an electrical component on a printed circuit board made of insulating member and having a surface conductive pattern on a surface thereof, according to claim 7, further comprising the step of:
placing a conductive sheet through which the internal conductive pattern can be connected to the predetermined electrical component mounted in the concave portion, on the internal conductive pattern.

10. A method for mounting an electrical component on a printed circuit board made of insulating member and having a surface conductive pattern on a surface thereof, according to claim 8, further comprising the step of:
placing a conductive sheet through which the internal conductive pattern can be connected to the predetermined electrical component mounted in the concave portion, on the internal conductive pattern.

11. A method for mounting an electrical component on a printed circuit board made of insulating member and having a surface conductive pattern on a surface thereof, comprising the steps of:
forming a through hole for passing through the printed circuit board, wherein a predetermined electrical component can be mounted;
forming an internal conductive pattern for connecting a predetermined electrical component mounted in the through hole to another electrical component mounted on the surface conductive pattern; and
mounting a predetermined electrical component in the through hole so as to be connected to the internal conductive pattern.

12. A method for mounting an electrical component on a printed circuit board made of insulating member and having a surface conductive pattern on a surface thereof, according to claim 11,
wherein the concave portion is formed at a position on the printed circuit board so that a length of the internal conductive pattern is shortest.
